(19) United States
(12) Patent Application Publication
(10) Pub. No.: US 2013/0105969 A1
(43) Pub. Date: May 2, 2013

(54) SOLDER BONDING PROCESS FORMING A SEMICONDUCTOR CHIP IN MULTIPLE STAGES ON A 3-DIMENSIONAL STACKED ASSEMBLY

(71) Applicant: International Business Machines Corporation, Armonk, NY (US)

(72) Inventor: Akihiro Horibe, Kanagawa-ken (JP)

(73) Assignee: International Business Machines Corporation, Armonk, NY (US)

(21) Appl. No.: 13/658,180

(22) Filed: Oct. 23, 2012

(30) Foreign Application Priority Data
Oct. 27, 2011 (JP) 2011-235876

(51) Int. Cl. B23K 31/02; B23K 1/20; H01L 23/498

(52) U.S. Cl. 257/737; 228/227; 228/203; 257/E23.068

(57) ABSTRACT

A method of performing primary solder bonding of a semiconductor chip to an organic interposer, and secondary solder bonding of the organic interposer to a motherboard and a 3-dimension stacked assembly structure formed by the method thereof. The method includes: providing on the organic interposer, a first solder bump, where the first solder bump has a solder material of a relatively high melting point stacked on a solder material of a relatively low melting point; heating the first solder material to a first temperature that melts the solder material of a relatively low melting point but does not melt the solder material of a relatively high melting point; sealing, using an underfill material, the gap between the semiconductor chip and the organic interposer; and heating the first solder bump to a second temperature that melts the solder material of a relatively high melting point.

### CROSS-REFERENCE TO RELATED APPLICATIONS

This application claims priority under 35 U.S.C. §119 to Japanese Patent Application No. 2011-235876 filed Oct. 27, 2011, the entire contents of which are incorporated by reference herein.

### BACKGROUND OF THE INVENTION

1. Field of the Invention

This invention relates to solder bonding processes for semiconductor chips. More specifically, it relates to formation technology for 3-dimensional stacked assemblies and 3-dimensional stacked devices that perform primary solder bonding of a semiconductor chip to an organic interposer and secondary solder bonding of the organic interposer to a motherboard.

FIG. 1 is a pattern drawing that shows the formation process for a 3-Dimensional stacked assembly (3-dimensional stacked device) that performs primary solder bonding of a semiconductor chip to an organic interposer and a secondary solder bonding of the organic interposer to a motherboard.

Each of the three pieces, being the semiconductor chip, the organic interposer, and the motherboard, is a “substrate” that will be stacked and solder bonded.

2. Description of the Related Art

FIG. 2 is a drawing that shows a solder bump application example of the former technology, by introducing a Former Type Solder Bump Example 1 and a Former Type Solder Bump Example 2.

With a 3-Dimensional stacked assembly, the sought capabilities are to: easily perform an electrical connection to the metal of a solder bump joint intended to take an electrical connection; possess suitable strength between the multiple substrates to be stacked, from the standpoint of the mechanical strength required; and maintain a fixed gap in order to enable filling of a sealing resin for joint protection.

In FIGS. 1 and 2, the solder bumps are drawn with exaggerated size, but they are actually fine, and the clearance (gap) formed by the solder bumps between the substrates is quite narrow.

In addition, from the solder bump, durability is sought against electromigration (EM), initiated by the current at device activation. When a comparatively brittle material is placed between a semiconductor chip and a solder bump as an insulating layer for a wiring layer of the semiconductor chip, called a Low-k layer, flexibility is needed so that breakage will not occur at the joint.

As shown in Former Type Solder Bump Example 1, only one type of solder material is used for the solder bump material of the 3-Dimensional stacked assembly that has a through electrode (TSV: through silicon via), and when bonding to one substrate, there is an ability to maintain a preferred gap between the chip by controlling the height while applying heat to the melted bump. However, because the same heat and load are applied when stacking the next substrate, the bump of the first joint re-melts and the gap between the chips cannot be maintained. The result is that the melted solder breaks and shorts between the electrodes are generated.

On this point, as shown in Former Type Solder Bump Example 2, for the purpose of maintaining a gap, a structure can be used that has stacked a copper post of a prescribed height and a solder material. In following this method, there is an ability to maintain a gap that corresponds to the height of the copper post, but the portion of the solder layer not being an metal intermetallic compound will be pushed to the periphery of the bump at the time of stacking, not remaining at the joint, so that only the intermetallic compound layer remains.

The remaining intermetallic compound layer has mechanically hard and fragile properties. Accordingly, there is generated mechanical stress such as warping caused by the difference in the coefficient of thermal expansion (CTE) between the chip and the organic substrate on which it has been mounted, and when a mechanical stress is applied from the exterior, at the joint constituting only of this copper post and intermetallic compound, there is no flexible region that can absorb the stress, and therefore breakage easily occurs at the relatively fragile intermetallic compound layer. Therefore, in a situation where placing a flexible lead-free solder that will not become an intermetallic compound, it is preferable to complement the bond by the sealing with an underfill.

In addition, with a chip having attached an extremely thin through electrode, at the time of layer bonding, mechanical stress is added to the chip which is caused by the load or heat during heat bonding or by variations in height of the bump. However, with heating reflow that does not apply a load, a joint will not form if there is even mild warping of the chip, and subsequently it cannot be used. Accordingly, during subsequent mounting processes, it becomes necessary to release the stress on a heat bonded joint.

FIG. 3 is a drawing that representatively shows the temperature profile for a common mounting process with a semiconductor chip onto an organic interposer, and the stress received by the organic interposer along the temperature profile.

Normally, bonding of a bump metal is performed along such a temperature profile. However, a lead-free bump of SnAg, which is frequently used, has a melting point of approximately 220° C., which is hard in comparison to eutectic solder. After bonding is completed, due to the temperature change from 220° C. to 25° C. or room temperature, the organic substrate undergoes much thermal contraction, which results in the fragile Low-k layer of the semiconductor chip breaking at the base of the electrode joint.

Using a flexible low temperature solder with a low melting point in conjunction with a full metal electrode can address the above situation. However, there will be no durability against electromigration (EM), and therefore this cannot be adopted for high-end semiconductor chips.

Japan Unexamined Patent Application 3975569 discloses a technology that uses high melting point lead-free solder with a eutectic solder (lead solder), and bonds by melting only the lead solder. However, it does not utilize a process uses at the joint for the primary mounting a lead-free solder of high melting point having a melting point that will melt at the secondary mounting, seals with an underfill after the joint is completed, and causes eutectic melting of the two types of solder layers during secondary mounting.

There are no existing former technology examples of a process capable of establishing both a countermeasure for breakage (white bump) of the Low-k layer during primary mounting as well as reliability of the joint after secondary mounting.

### SUMMARY OF THE INVENTION

According to an aspect of the present invention, a method performs primary solder bonding of a semiconductor chip to an organic interposer, and secondary solder bonding of the organic interposer to a motherboard. The method includes: providing on the organic interposer, a first solder bump, where the first solder bump has a solder material of a relatively high melting point stacked on a solder material of a relatively low melting point; heating the first solder material to a first temperature that will melt the solder material of a relatively low melting point but will not melt the solder material of a relatively high melting point; sealing, by use of an underfill material, the gap between the semiconductor chip and the organic interposer; and heating the first solder bump to a second temperature that will melt the solder material of a relatively high melting point, when solder bonding the organic interposer to the motherboard.

According to another aspect of the present invention, a 3-dimensional stacked assembly structure is formed by using a method of performing primary solder bonding of a semiconductor chip to an organic interposer, and secondary solder bonding of the organic interposer to a motherboard. The 3-dimensional stacked assembly structure includes: the organic interposer; and a first solder bump, where the first solder bump has a solder material of a relatively high melting point stacked on a solder material of a relatively low melting point and where the semiconductor chip, the organic interposer, and the motherboard have been solder bonded.

### BRIEF DESCRIPTION OF THE DRAWINGS

FIG. 1 is a pattern drawing that shows the formation process for a 3-Dimensional stacked assembly (3-dimensional stacked device) that performs primary solder bonding of a semiconductor chip to an organic interposer and a secondary solder bonding of the organic interposer to a motherboard according to an embodiment of the present invention.

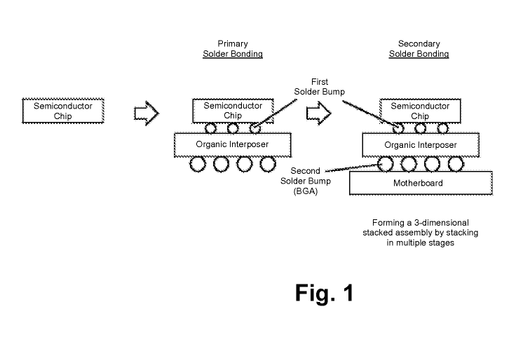

FIG. 2 is a drawing that shows a solder bump application example of the former technology, by introducing a Former Type Solder Bump Example 1 and a Former Type Solder Bump Example 2.

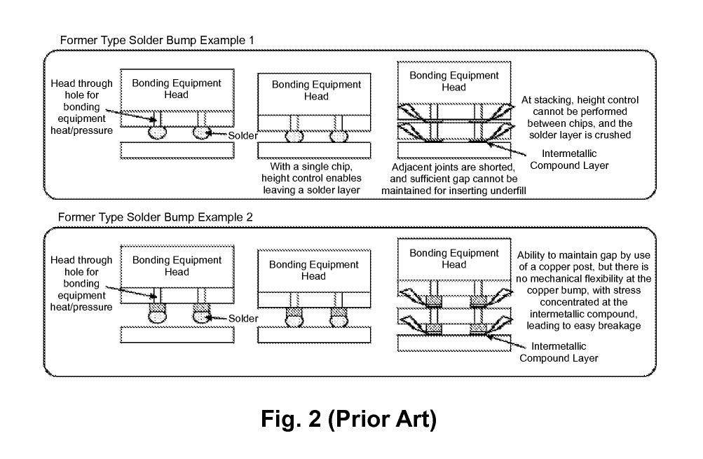

FIG. 3 is a drawing that representatively shows the temperature profile for a common mounting process with a semiconductor chip onto an organic interposer, and the stress received by the organic interposer along the temperature profile.

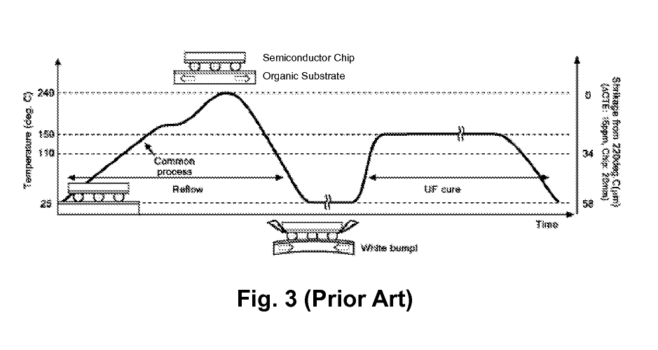

FIG. 4 is a drawing that compares common process A with process B, where process B is according to an embodiment of the present invention.

FIG. 5 is a drawing that explains the structure, for which process B was used, that has stacked, a low melting point solder and a high melting point solder according to an embodiment of the present invention.

FIG. 6 is a cross-section drawing of a solder bump according to an embodiment of the present invention.

### DETAILED DESCRIPTION OF PREFERRED EMBODIMENTS

A gap and bump shape can be maintained during secondary mounting to a motherboard, specifically, a discretionary height can be maintained where it is standardized by the height of a high temperature melting point solder, without the joint breaking by load or heat applied by heat or pressure bonding during multistage stacking (secondary).

Because this solder bump is already sealed by an underfill, the chip will not slip a great deal, even if the high melting point solder component melts, and there is no breaking of the high melting point solder layer that has melted.

By coating and hardening the underfill at a temperature lower than the melting point of the low temperature solder, there is an ability to fix the gap between the chips and the bump shape, and mounting is possible in a condition where optimal clearance between electrodes and between substrates of the 3-dimensional stacked structure is maintained during while mounting to a substrate.

As a result, a 3-Dimensional stacked assembly can be produced that is highly reliable at low cost and without the concentration of stress.

In addition, even after bonding the solder of the electrical joint, the entire solder component remains without becoming an intermetallic compound, and therefore it possesses suitable flexibility and the low melting point solder being of a relatively small amount is dispersed through the high melting point solder. The high melting point solder component becomes the main body, which results in a bump that is superior from the viewpoint of EM durability.

Furthermore, a reflow bonding process can be utilized that uses heat and only the weight of the product itself, without applying a load during the secondary mounting, and therefore providing the capability to melt the high melting point solder in order to release a large amount of stress remaining in an extremely thin chip with through electrodes that has been added during multi-chip stacking.

Embodiments of the present invention include a bonding process with durability against electromigration (EM), that can be adopted for high-end semiconductor chips, and which forms in multiple layers a semiconductor chip on a 3-Dimensional stacked assembly.

A 3-Dimensional stacked assembly can be created by, using at the electrical joint, two types of solder having different melting points, and layer bonding can be performed by melting only the low temperature solder during chip stacking (primary), and by performing sealing with an underfill.

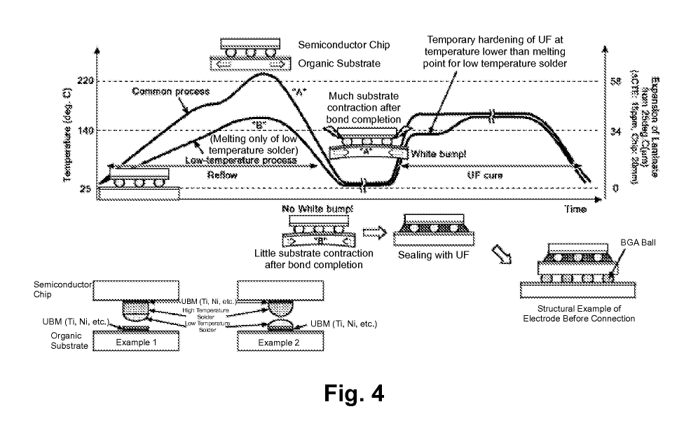

FIG. 4 is a drawing that compares common process A with process B, where process B is an embodiment of the present invention.

With common process A, heat is applied to the vicinity of 220° C. in order to melt the solder bump. In comparison to the coefficient of thermal expansion (CTE) of the chip, the coefficient of thermal expansion (CTE) of the organic interposer is larger, and therefore the organic interposer expands (substrate expansion) only by the difference between them (delta CTE), which is approximately 15 ppm.

Next, lowering of the temperature occurs in order to complete the solder joint by cooling the melted solder, but the organic interposer contracts (substrate contraction) during this temperature change process.

In comparison to common process A, process B is completed by melting only the low temperature solder, and the drop is small for the change in temperature in comparison to process A, thereby completing with little substrate contraction after joint completion.

With process B, there is structuring by stacking at the electrical joint two types of solder that have differing melting points, and this layer bonding melts only the low temperature solder when performing substrate stacking for the 3-Dimensional stacked assembly. In this way, a discretionary height is maintained based to the height of the high-temperature solder, without the joint breaking due to load or heat applied by heat or pressure bonding during the multilayer process.

Specifically, a layer bonding is performed on only the low melting point bump at the time of chip layer bonding of a 3-dimensional chip, and, at this time, the high melting point solder, by not melting, performs the role of a spacer for maintaining a gap between the chips.

In continuation, coating and hardening (or semi-hardening) of the underfill is performed. This is done by sealing an underfill. However, for the temperature of the coating and hardening (curing), it is preferable to use a temperature lower than the melting point of the low melting point solder.

With a two-step hardening process, it is acceptable for the hardening temperature to surpass the melting point of the low melting point solder, as long as it is after a time at which the liquidity of the underfill has become sufficiently low. It is also acceptable to perform a secondary mounting in a semi-hardened condition, as long as the liquidity has become sufficiently low.

The usage method for the underfill is not limited to the post-bonding capillary method, and it may be such a method as a pre-coating method, where resin hardening is performed simultaneous to the bonding.

Subsequently, the high melting point solder component of the underfill sealed bump is melted at the time of the secondary mounting of the stacked chip, and the entire joint is homogenized as basically a high melting point solder component.

Moreover, melting the high melting point solder enables the release of the residual stress within the stacked chip, which can cause variation in the load, thermal history, or height of the bump when bonding the multiple layers of the chip. This alleviates mechanical stress that remains in an extremely thin chip possessing a through electrode, unique to 3-dimensional semiconductor devices, and improves the reliability of a 3-Dimensional stacked assembly.

By melting the high melting point solder between the stacked chips during secondary mounting, the high melting point solder that forms the majority of the electrode melts with the small amount of low melting point solder that remains, and a solder connection is formed having reliability near that of the high melting point solder.

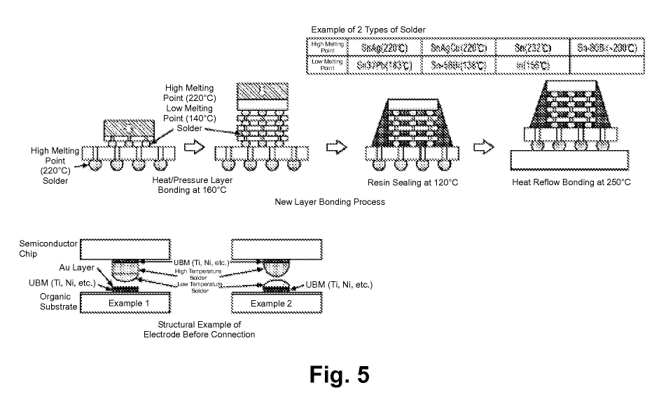

FIG. 5 is a drawing that explains the structure, for which process B was used, that has stacked, a low melting point solder and a high melting point solder.

The (first) solder bump is formed by stacking a solder material of a relatively high melting point (high melting point solder) on a solder material of a relatively low melting point (low melting point solder). As long as the low melting point solder is presented to the organic interposer, it is acceptable to present the low melting point solder with the high melting point solder, as in Example 1, or to present the low melting point solder from the organic interposer side (separated from the high melting point solder), as in Example 2.

Regarding the constituents of the two types of solder material used in the 3-dimensional multilayer substrate, the high melting point solder includes at least SnAg, SnAgCu, or at least Sn, and, in order to melt at the secondary mounting, constituents are used that possess a melting point equal to or under that of the electrode material that bonds during secondary mounting. In this way, when loaded on the organic substrate, there is an ability to alleviate the stress that is applied to the stacked chip by thermal expansion of the substrate.

Additionally, the low melting point solder includes at least one of Sn, Bi, or In, in order to set the melting point of 20° C. or more lower than the previously described high melting point solder.

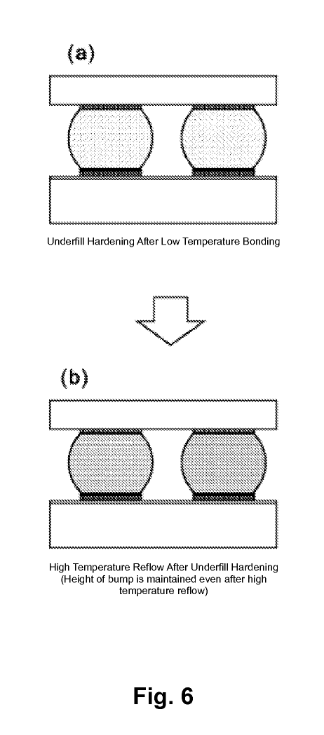

FIG. 6 is a cross-section drawing of a solder bump according to an embodiment of the present invention.

The melting point of the solder material with a relatively low melting point which structures the first solder bump is 140° C., and the melting point of the solder material with a relatively high melting point which structures the first solder bump is 220° C. Sealing is performed by an underfill material, coated at 110° C., with preliminary hardening at 120° C., and main hardening at 150° C. The melting point of the second solder bump is 220° C., being the same as that of the first solder bump high melting point constituent, and shown by experimentation to pass through a presumed second mounting reflow temperature of 250° C.

In this embodiment of the present invention, after high temperature reflow, the height of the solder bump can be favorably maintained.

In this embodiment of the present, invention, application outside specified narrow (absolute) temperature conditions is possible; as long as the melting points, coating temperature, hardening temperature, and bonding temperature are set and implemented with a relative relationship, the technical idea of the embodiment of the present invention can be carried out.

The embodiments of the present invention have been explained as a solder bond for three types of “substrate,” a semiconductor chip, an organic interposer, and a motherboard, but the technical idea of the present invention can be widely applied, without limitation to these three types of “substrate,” as long as there is commonality of the problem to be solved. There is no limited meaning in the expressions “semiconductor,” “organic,” or “mother,” with these expressing that they are substrates of relatively different properties, used for convenience in the explanation as substrates expected to bear unique roles.

What is claimed is:

1. A method for performing primary solder bonding of a semiconductor chip to an organic interposer, and secondary solder bonding of the organic interposer to a motherboard, the method comprising:
providing on the organic interposer, a first solder bump, wherein the first solder bump has a solder material of a relatively high melting point stacked on a solder material of a relatively low melting point;
heating the first solder material to a first temperature that will melt the solder material of a relatively low melting point but will not melt the solder material of a relatively high melting point;
sealing, by use of an underfill material, the gap between the semiconductor chip and the organic interposer; and
heating the first solder bump to a second temperature that will melt the solder material of a relatively high melting point, when solder bonding the organic interposer to the motherboard.

2. A method according to claim 1, further comprising:
prior to heating the first solder bump to the second temperature that will melt the solder material of a relatively high melting point, presenting on the motherboard, a second solder bump that will melt at the second temperature.

3. A method according to claim 1, wherein:
the solder material with a relatively low melting point is a material selected from the group consisting of: Sn, Bi, and In; and
the solder material of a relatively high melting point is a material selected from the group consisting of: SnAg, SnCu, SnAgCu, and an alloy that includes Sn.

4. A method according to claim 1, wherein a Low-k layer is disposed between the semiconductor chip and the first solder bump to be presented.

5. A method according to claim 2 wherein:
the melting point of the solder material of a relatively low melting point which structures the first solder bump is 140° C.;
the melting point of the solder material of a relatively high melting point that structures the first solder bump is 220° C.;
the step of sealing, by use of the underfill material, is performed by coating at 110° C. and at least preliminary hardening at 120° C.; and
the melting point of the second solder bump is 220° C.

6. A 3-dimensional stacked assembly structured by a method of performing primary solder bonding of a semiconductor chip to an organic interposer, and secondary solder bonding of the organic interposer to a motherboard, the 3-dimensional stacked assembly structure comprising:
the organic interposer; and
a first solder bump;
wherein the first solder bump has a solder material of a relatively high melting point stacked on a solder material of a relatively low melting point; and
wherein the semiconductor chip, the organic interposer, and the motherboard have been solder bonded.
